(19) United States
(12) Patent Application Publication
(10) Pub. No.: US 2011/0304985 A1
(43) Pub. Date: Dec. 15, 2011

(54) ELECTRICAL OR ELECTRONIC COMPOSITE COMPONENT AND METHOD FOR PRODUCING AN ELECTRICAL OR ELECTRONIC COMPOSITE COMPONENT

(76) Inventors: Martin Rittner, Freiberg (DE); Erik Peter, Ludwigsburg (DE); Michael Guenther, Stuttgart (DE)

(21) Appl. No.: 13/141,947

(22) PCT Filed: Dec. 7, 2009
(86) PCT No.: PCT/EP09/66518

§ 371 Date: Aug. 30, 2011

(30) Foreign Application Priority Data
Dec. 23, 2008 (DE) 102008055134.1

(51) Int. Cl. H05K 7/20; B32B 37/02; B32B 37/14; B32B 37/10; B32B 37/12; H05K 13/00; B32B 37/06

(52) U.S. Cl. 361/688; 156/60; 156/306.6; 156/73.1

(57) ABSTRACT

An electrical or electronic composite component is described as having a first joining partner and at least one second joining partner. According to the present system, it is provided that a sintered compact having open porosity is accommodated between the first and the second joining partner, the sintered compact is connected fixedly to the first and to the second joining partner.

### FIELD OF THE INVENTION

The present invention relates to an electrical or electronic composite component, and to a method for producing an electrical or electronic composite component.

### BACKGROUND INFORMATION

The joining of power semiconductors, such as JFETs, MOSFETs, IGBTs, or diodes, to a circuit substrate of a power electronics assembly, and also the joining of the circuit substrate to a baseplate/heat sink, are typically realized using soft solder technology. Based on new EU regulations, in the future the use of soft solder alloys containing lead (Sn63Pb37 and Sn5Pb95) is to be forbidden. Lead-free soft solder alloys based on SnAgCu may be used as substitute alloys only to a certain extent, because these are limited in their reliability, in particular under passive and active temperature change stress. Alternative high-melting-paint soft solders used as substitute alloys are either too brittle to handle (Bi97, 5Ag2.5) or are too expensive (Au80Sn20).

The immediate sintering of joining partners using silver paste is known as an alternative joining technology that withstands high temperatures and is highly reliable. This technology is called low-temperature joining technology. A distinction is made between two different possible realizations, namely the sintering of silver metal flakes, as is discussed in EP 2 246 26 B1, and the sintering of silver metal nanoparticles, as discussed in WO 2005/079353 A2. In contrast to a soldering process, during sintering the (sintered) particles do not enter the liquid phase; i.e., they do not melt.

In the sintering of silver metal flakes, atmospheric oxygen is used for the combustion of the ground waxes; this requires a temperature of approximately 240° C. and a high process pressure of approximately 40 MPa. The sintering of silver metal nanoparticles offers the option of carrying out the sintering process with significantly lower pressure, in a pressure range between approximately 100 kPa and 5 MPa. As in the sintering of silver metal flakes, in the sintering of nanoparticles oxygen and a process temperature of approximately 280° C. are required. In addition, the known silver metal nanoparticle paste formulation contains an even higher organic portion, such as solvent and/or binding agent, than do paste formulations based on silver metal flakes. In the known method, sintering paste is applied directly onto the first and/or second joining partner, whereupon the joining partners are pressed against one another under the action of temperature. When the process is carried out using sintering paste, there is the difficulty that high volumes of gas have to be exchanged through the sintering layer; thus, oxygen must reach the joining points, and the solvents, as well as combusted/oxidized organic materials, must be able to exit. In particular at the desired low process pressures, this results in an increased formation of cracks, in particular given joining over large surfaces.

### SUMMARY OF THE INVENTION

The exemplary embodiments and/or exemplary methods of the present invention are based on the object of proposing an electronic or electrical composite component, as well as a manufacturing method for such a composite component, in which crack formation during joining can be avoided. The composite component may be producible at low cost, and reliable under the stress of changes of temperature.

With regard to the electrical or electronic composite component, this object is achieved by the features described herein, and with regard to the manufacturing method it is achieved by the features described herein. Advantageous developments of the exemplary embodiments and/or exemplary methods of the present invention are indicated herein. All combinations of at least two features disclosed in the description and/or the Figures fall within the scope of the present invention. In order to avoid repetition, features disclosed with respect to the device shall be considered valid and claimable with respect to the method. Likewise, features disclosed with respect to the method shall be considered valid and claimable with respect to the device.

An important aspect of the exemplary embodiments and/or exemplary methods of the present invention is to join at least two joining partners to one another not directly using sintering paste, as in the prior art, i.e. fixing them solidly together, but rather to connect the joining partners fixedly without using sintering paste, using a previously produced sintered compact having continuous open porosity. The thickness of the sintered compact (sintered foil) that is used may be between approximately 10 μm and approximately 300 μm or more in the direction of stacking of the joining partners. Such a sintered compact has the advantage of gas channels that are already integrated and that are stable in the following process of joining to the joining partners, for the aeration and de-aeration of the joining points that are formed for example by soldering, welding, or gluing. The use of a porous sintered compact as an insert or intermediate part has a positive effect on the joining process for joining the joining partners to the sintered compact, in particular if joining partners having large surfaces, such as silicon power semiconductors and circuit substrates, or circuit substrates and heat sinks, are to be joined to the sintered compact. It is also possible to connect punched grids via a sintered compact. A further advantage of the use of a sintered compact is that it provides more freedom in the design of the joining point, because the sintered compact can have a larger surface than at least one of the joining partners, which may be than both the joining partners, and/or the joining partners can be situated significantly further from one another than is possible in the process controlling according to the prior art, i.e. given an immediate sintering of the joining partners using sintering paste. In particular, the advantage is an increased ability to withstand changes in temperature.

The exemplary embodiments and/or exemplary methods of the present invention can be used in a large number of electrical and/or electronic applications. Particularly preferred is its realization in power electronics modules required for example for many forms of energy conversion, in particular mechanical/electrical (generators, rectifiers), electrical/electrical (converters, AC/AC, DC/DC), and electrical/mechanical (electrical drives, inverting). In addition, correspondingly fashioned power electronics modules for rectification can be used in a motor vehicle generator, for the controlling of electrical drives, for DC/DC converters, for a pulse-controlled inversion, for hybrid/FC/electric drives, and for photovoltaic inverters, etc. In addition or alternatively, individual components having higher power losses, in particular discrete packages on the punched grids, can be joined according to the present invention, and can then, for example for the case in which lead is not to be used, be used as completely lead-free solutions in circuit board technology.

Particularly preferred is the realization of the present invention in constructions having semiconductor laser diodes, or in MEMs and sensors, in particular for high temperature applications. Further examples of applications are semiconductor LEDs and high-frequency semiconductors for radar applications.

Quite particularly, there is a specific embodiment of the composite component in which the sintered compact is made of silver metal, in particular silver metal flakes, and/or includes silver metal, in particular silver metal flakes. Sintered compacts made of silver metal or including silver metal are advantageous with regard to their high electrical and thermal conductivity. In addition, silver is suitable for realizing a continuous open porosity that forms gas channels.

With regard to the joining of the at least two joining partners to the sintered compact, there are various possibilities; the choice of an identical method for the two joining partners or of different methods for them lies within the scope of the present invention. According to a first alternative, the first and/or second joining partner is/are sintered to the sintered compact without the use of additional sintering paste. For this purpose, it is necessary merely to apply sufficient pressure and temperature so that the sintered compact enters into a bond with the at least one joining partner, i.e. becomes sinterable.

Alternatively, it is possible to solder at least one joining partner, which may be both joining partners, to the sintered compact, which may be done by using soldering paste, soldering powder, or a solder perform (generally: soldering material). Here, due to the action of temperature the soldering material enters a liquid phase and binds the sintered compact to the at least one joining partner. Quite particularly, the soldering material may be lead-free soldering paste, but it is also conceivable to use soldering pastes containing lead, in particular standard soldering pastes. Due to its porous structure, the sintered compact that is used is highly suitable for entering into a robust soldering bond. This is due above all to the good wettability of the sintered compact with all standard soldering materials, in particular if the sintered compact is made at least partly of silver metal, in particular silver metal flakes. The “buffering” effect of the sintered compact significantly reduces the destructive effect that thermomechanical tensions have on the pure soldering material, in particular during the later use of the electrical or electronic composite component. The soldering material that is used, in particular soldering paste, may be either applied, in particular pressed on or dispensed, both to the joining partners and to the sintered compact, which then acts as a depot, or alternatively is applied only to both sides of the sintered compact, or, as a further alternative, is applied only to one side of the sintered compact and to only one joining partner. The gases that arise during the soldering process can optimally be carried off through the gas channels formed by the porosity of the sintered compact. It is also possible, in a soldering paste pressure process carried out before the actual soldering process, to apply a solder depot to the later joining points for the fitting of SMD components and subsequent reflow soldering. In this case, it is necessary merely to further apply flux to these points. The porous structure of the sintered compact provides sufficient possibilities for the degassing of the flux system.

Another possibility for connecting at least one joining partner to the sintered compact is to glue the joining partner to the sintered compact, in particular by conductive gluing. Here, it may further be preferred for glues to be used that contain silver (are filled with silver), which finds an ideal bonding surface in the sintered compact.

In addition, it is possible to connect at least one of the joining partners to the sintered compact by welding, in particular frictional welding, ultrasound welding, or resistance welding. The surface of the sintered compact, which may be made of silver or contains silver, can optimally be connected to at least one joining partner, and which may be to both joining partners, in a welding process.

With regard to the construction of the first and the second joining partners, there exists a wide range of possibilities resulting in a wide range of different composite components. Quite particularly, the first joining partner may be an electronic component, which may be a semiconductor component, quite particularly which may be a power semiconductor that can be connected via a sintered compact to the second joining part, in particular a circuit substrate (circuit board). It is also possible to connect, via a sintered compact, a first joining partner fashioned as a circuit substrate to a second joining partner preferably fashioned as a base plate, in particular made of copper. The copper base plate may act as a heat sink or may be connected to a cooling element that acts as a heat sink. It is also possible to connect the cooling element (first joining partner) to the base plate (second joining partner) via a sintered compact. In addition, it is possible to connect, i.e. to contact, via a sintered compact, at least one bonding wire or at least one bonding belt to a further joining partner, in particular an electronic component, which may be a semiconductor component, in particular a power semiconductor component or a circuit substrate (electrical component). Here, the sintered compact has the effect of increasing reliability. It is also possible for the first joining partner to be for example an electrical component, in particular a punched grid (conductor grid) that can be connected via a sintered compact to a second joining partner, in particular to a circuit substrate, more precisely to a metal of the circuit substrate. Previously, punched grids were soldered directly onto a circuit board (circuit substrate), often resulting in enclosed pores/hollow spaces (cavities). Furthermore, using known process controlling, the joining gap fluctuates greatly, so that reliability under the stress of temperature and changes of temperature is not always present, or cannot always be guaranteed. Further combinations of first and second joining partners resulting from the claims can also be realized.

The use of sintered compacts is not limited to composite components having only two joining partners. Thus, for example it is conceivable to produce a composite component having two or even more sintered compacts, at least two joining partners being fixed to one another via each sintered compact. In this way, a sandwich-type construction can be produced comprising three or more joining partners, the joining partners and the sintered compacts may be stacked in a direction of stacking. Thus, for example a second joining partner formed by a power semiconductor can be connected at both sides, via a respective sintered compact, to a circuit substrate that forms a first or, respectively, a second joining partner, so that the power semiconductor is sandwiched between the circuit substrates, a sintered compact being situated between each circuit substrate and the power semiconductor. The sandwich construction need not necessarily be realized in one process step, but rather can for example also be produced in two or more steps.

The exemplary embodiments and/or exemplary methods of the present invention is also directed to a method for producing an electrical or electronic composite component, which may be a composite component fashioned as described above. The core of the method is to connect at least two joining partners to a sintered part (sintered foil) having open porosity, which may be by immediate sintering without using sintering paste, by soldering using a soldering material, in particular lead-free soldering material, which may be soldering paste, by gluing, in particular conductive gluing, which may be done using a glue containing silver, or alternatively by welding, in particular frictional welding, ultrasound welding, or resistance welding. The advantage of the method according to the present intention is that the continuous open porosity of the structure of the sintered compact allows gases to escape during the process of connecting to the joining partners, and as needed gases such as oxygen can be conducted to the joining points so that crack formation is avoided. The conducting away of gas and the supply of gas may take place from the lateral direction, i.e. transverse to the stacking direction of the joining partners.

Further advantages, features, and details of the present invention result from the following description of the exemplary embodiments, and on the basis of the drawings.

### BRIEF DESCRIPTION OF THE DRAWINGS

FIG. 1 shows a power electronics composite component (here a power electronics assembly/module).

FIG. 2 shows a sectional representation of a sintered compact for connecting two joining partners to one another.

FIG. 3 schematically shows a process for producing an electrical or electronic composite component having two joining partners.

FIG. 4 schematically shows a process for producing an electrical or electronic composite component having three joining partners and two sintered compacts.

### DETAILED DESCRIPTION

In the Figures, identical elements, and elements having identical function, are identified by the same reference characters.

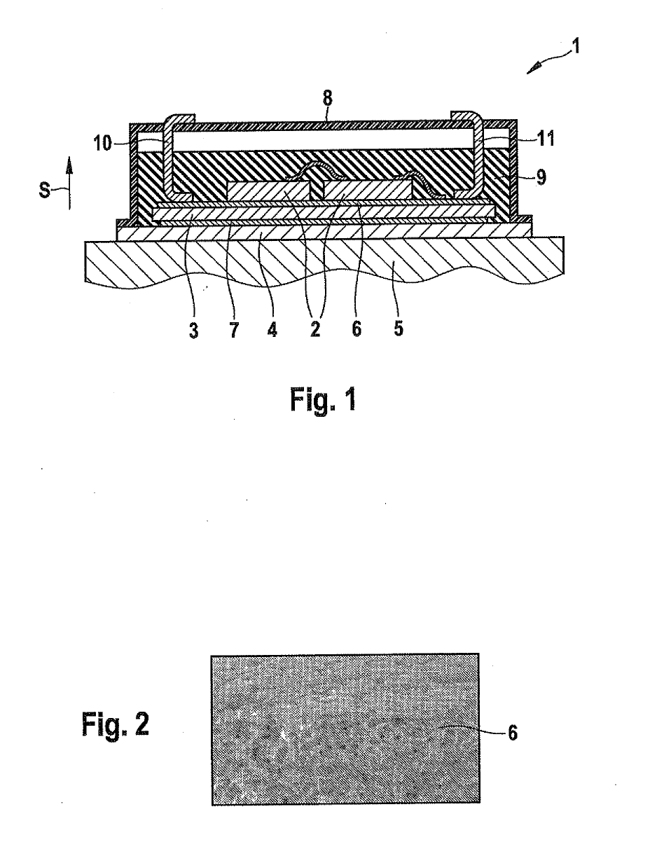

FIG. 1 shows an electronic composite component 1. This component has a first joining partner 2, a second joining partner 3, and a third joining partner 4. In the depicted exemplary embodiment, first joining partner 2 is a power semiconductor component, here an 1 GB transistor. Second joining partner 3 is a circuit substrate, and third joining partner 4 is a base plate made of copper. The base plate made of copper is in turn fixed to a cooling element 5 (heat sink).

Between first joining partner 2 and second joining partner 3 there is situated a sintered compact 6 having a thickness of approximately 5 μm in a stack direction S. First joining partner 2 and second joining partner 3 are fixed to two oppositely situated sides of sintered compact 6, in each case by soldering using soldering paste (or, alternatively, for example soldering powder or a solder preform). Sintered compact 6 is made of silver sintered material. Second joining partner 3 is in turn connected to third joining partner 4 via a further sintered compact 7 that is fashioned identically to sintered compact 6; here, third joining partner 4 and second joining partner 3 are each fixedly connected to further sintered compact 7 by soldering. Alternatively, sintered compacts 6, 7 can also be shaped differently from one another.

In the depicted exemplary embodiment, third joining partner 4 is directly soldered to cooling element 5. Alternatively (not shown), a sintered compact can also be provided between third joining partner 4 and cooling element 5, to which third joining partner 4 and cooling element 5 are fixed, for example by immediate sintering without sintering paste, by soldering, gluing, or welding.

FIG. 1 also shows that a plastic housing 8 is fixed to third joining partner 4 formed by the base plate, said housing surrounding the stack configuration comprising first and second joining partners 2, 3 and sintered compact 6. The so-called stack configuration is surrounded by an elastic protective compound 9. Connecting wires 10, 11 are guided through this compound up to the outer side of housing 8, and these connecting wires are fixed to second joining partner 3 (circuit substrate), contacting this joining partner, via sintered compact 6.

FIG. 2 shows the design of a sintered compact 6 made of silver metal flakes. The continuous open porosity can be seen here. This porosity forms gas channels through which gases can flow outward away from the join points, or can flow inward toward the join points. The gases may exit laterally, i.e. transverse to stack direction S (cf. FIG. 1), from the pores or from the gas channels formed by the pores, so that crack formation is avoided, in particular during a soldering process that may occur.

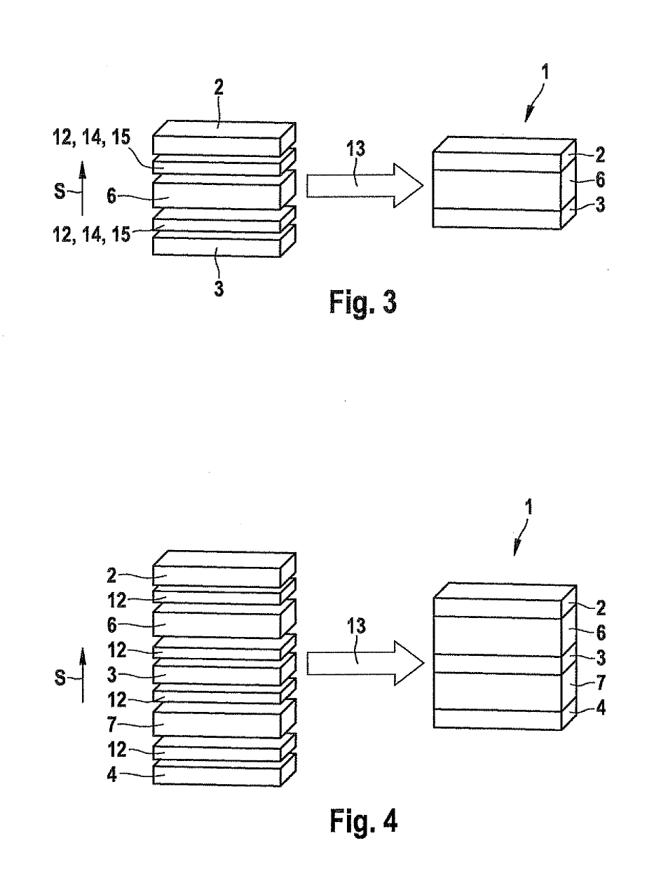

FIG. 3 shows a highly schematic view of the process for producing an electrical or electronic composite component 1, shown at right in the drawing. Said component has a first joining partner 2, shown at the top in the drawing, and a second joining partner 3, shown at the bottom in the drawing; these joining partners accommodate a sintered compact 6 sandwiched between them. First joining partner 2 is for example a chip and second joining partner 3 is for example a circuit substrate. Alternatively, it is conceivable for first joining partner 2 to be a circuit substrate and for second joining partner 3 to be a base plate, in particular made of copper, and/or a cooling element (heat sink). Further combinations, resulting from the claims, of first and second joining partners 2, 3 are alternatively realizable. In the depicted exemplary embodiment, first a soldering material 12, in particular soldering paste or a solder preform, is applied as a depot on the surfaces of both sides of sintered compact 6. Before the soldering, flux may be applied to the join points. After stacking in stack direction S, joining partners 2, 3, sintered compact 6, and soldering material 12 undergo a joining process 13, here a soldering process. The gas exchange for the soldering of soldering material 12 can take place via the overall porous volume of sintered compact 6.

An alternative joining process can be explained on the basis of FIG. 3. Thus, for example second joining partner 3 can be a circuit substrate, in particular the metal of a circuit substrate, typically copper or a copper alloy, and first joining partner 2 can be a punched grid, typically made of copper or a copper alloy. Glue 14, in particular silver-containing glue 14, can for example be pressed or dispensed onto second joining partner 3. If needed, sintered compact 6 can already have a depot of glue on the countersurface for first joining partner 2 (punched grid). Alternatively, glue 14 is applied as a glue depot in a subsequent process, for example dispensing. Subsequently, first joining partner 2 is placed onto glue 14 and is subjected to a hardening process, which may be under the action of temperature and/or pressure. Glue 14, or its components, can escape as gas through the porous structure of the sintered compact.

Furthermore, it is alternatively possible to connect at least one of joining partners 2, 3 to sintered compact 6 by welding. The welding process can, but need not necessarily, be carried out using an auxiliary material 15. If an auxiliary material is not used, the depots of auxiliary material according to FIG. 3 are not required.

FIG. 4 shows, at right in the drawing, a multipart electrical or electronic composite component 1. This component has a total of three joining partners 2, 3, 4, a sintered compact 6, 7 being situated between each two joining partners 2, 3; 3, 4. For example, first and third joining partners 2, 4 can be a circuit substrate, and central, i.e. inner, joining partner 3 can be a power semiconductor. The sandwich construction need not necessarily be joined in a common joining process; rather, a two-stage sequential process control can be realized, for example first joining first joining partner 2, sintered compact 6, and second joining partner 3, and then subsequently joining third joining partner 4, or, alternatively, first joining third joining partner 4, further sintered compact 7, and second joining partner 3, and then subsequently joining first joining partner 2.

1-17. (canceled)

18. An electrical composite component, comprising:
a first joining partner; and
at least one second joining partner, wherein a sintered compact having open porosity is accommodated between the first joining partner and the second joining partner, the sintered compact being connected fixedly to the first joining partner and to the second joining partner.

19. The composite component of claim 18, wherein the sintered compact is produced from silver metal, which includes silver metal flakes, and wherein the sintered compact includes silver metal, which includes silver metal flakes.

20. The composite component of claim 18, wherein at least one of the first joining partner and the second joining partner is one of (i) directly sintered to the sintered compact without additional sintering paste, (ii) soldered thereto, using soldering paste, (iii) welded thereto, using ultrasound welding, and (iv) glued thereto.

21. The composite component of claim 18, wherein the first joining partner is one of (i) an electronic component, which includes a power semiconductor component, (ii) a circuit substrate, which includes a metallization of the circuit substrate, (iii) a punched grid, (iv) a bonding wire, (v) a bonding belt, and (vi) a base plate.

22. The composite component of claim 18, wherein the second joining partner is one of (i) an electronic component, which is a power semiconductor component, (ii) a circuit substrate, which includes a metallization of the circuit substrate, (iii) a base plate, which is made of copper, and (iv) a cooling element.

23. The composite component of claim 18, wherein at least one of (i) a further sintered compact is accommodated between the first joining partner and one of a third joining partner and a fourth joining partner, and (ii) a further sintered compact is accommodated between the second joining partner and one of the third joining partner and the fourth joining partner, the further sintered compact being one of (i) sintered directly to the adjacent joining partners without sintering paste, (ii) soldered thereto, (iii) welded thereto, and (iv) glued thereto.

24. The composite component of claim 23, wherein at least one of the third joining partner and the fourth joining partner is (i) an electronic component, which includes a power semiconductor component, (ii) a circuit substrate, in particular a metallization of the circuit substrate, (iii) a base plate, which is made of copper, and (iv) a cooling element.

25. A method for producing an electrical composite component, the method comprising:
fixedly connecting a first joining partner and a second joining partner to a sintered compact having open porosity, wherein the sintered compact having open porosity is accommodated between the first joining partner and the second joining partner, and wherein the sintered compact is connected fixedly to the first joining partner and to the second joining partner.

26. The method of claim 25, wherein the first joining partner and the second joining partner are fixed to two sides of the sintered compact that face away from one another.

27. The method of claim 25, wherein at least one of the first joining partner and the second joining partner are sintered directly to the sintered compact without sintering paste, which is done in a common sintering step under the action of at least one of temperature and pressure.

28. The method of claim 25, wherein at least one of the first joining partner and the second joining partner are soldered to the sintered compact, using soldering paste.

29. The method of claim 28, wherein before the joining the soldering paste, a flux, is applied, which is pressed or dispensed, onto at least one of the first joining partner, the second joining partner, and the sintered compact.

30. The method of claim 25, wherein the first joining partner and the second joining partnerare welded to the sintered compact, with or without an auxiliary material.

31. The method of claim 25, wherein the first joining partner and the second joining partner are welded to the sintered compact, using ultrasound welding, with or without an auxiliary material.

32. The method of claim 25, wherein at least one of the following is satisfied: (i) a further sintered compact is situated between the first joining partner and one of a third joining partner and a fourth joining partner, and (ii) a further sintered compact is situated between the second joining partner and a third joining partner and a fourth joining partner, the sintered compact being one of directly sintered, soldered, welded, and glued to the adjacent joining partners.

33. The method of claim 32, wherein the fixing of the further sintered compact to one of the first joining partner and the second joining partner, and the fixing of the sintered compact to the first joining partner and the second joining partner is performed in a common process step or in separate process steps.

34. The method of claim 25, wherein a sintered part is separated into a multiplicity of sintered compacts.
